(19) United States
(12) Patent Application Publication
(10) Pub. No.: US 2026/0213745 A1
(43) Pub. Date: Jul. 23, 2026

(54) DRIVER CHIP, SEMICONDUCTOR PACKAGE AND METHOD FOR DRIVING A POW-ER TRANSISTOR

(71) Applicant: Infineon Technologies Austria AG, Villach (AT)

(72) Inventors: Michael SIEBERER, Graz (AT); Thomas FERIANZ, Bodensdorf (AT)

(21) Appl. No.: 19/451,074

(22) Filed: Jan. 16, 2026

(30) Foreign Application Priority Data
Jan. 22, 2025 (DE) 102025102214.3

(51) Int. Cl. H03K 17/16; H02K 11/33

(52) U.S. Cl. CPC H03K 17/162; H02K 11/33

(57) ABSTRACT

A driver chip configured to drive a gate of a power transistor comprises: a slope reference configured to provide a first voltage, an output configured to be connected to a gate terminal of a power transistor, a shaping capacitor configured to be connected between the slope reference and a drain terminal of the power transistor, and a buffer connected between the slope reference and the output and configured to be provided with the first voltage.

### RELATED APPLICATION

This application claims priority to earlier filed German Patent Application Serial Number 10 2025 102 214.3 entitled “DRIVER CHIP, SEMICONDUCTOR PACKAGE AND METHOD FOR DRIVING A POWER TRANSISTOR,” filed on Jan. 22, 2025, the entire teachings of which are incorporated herein by this reference.

### TECHNICAL FIELD

The present disclosure relates to a driver chip configured to drive a gate of a power transistor, to a semiconductor package comprising a driver chip, and to a method for driving a power transistor.

### BACKGROUND

Power electronics applications like switched-mode power supplies or motor drive applications comprise switches, i.e. power transistors, that are switched between an on-state and an off-state. This switching may cause significant electromagnetic interference (EMI). The amount of generated EMI may depend on the specific switching conditions. For example, radiated EMI may be a function of dV/dt and conducted EMI may be a function of dl/dt, wherein V denotes the voltage over the switch and I denotes the current through the switch. Depending on the specific application, it may be necessary to apply extensive EMI-filters in order to mitigate radiated EMI which may lead to increased costs and/or increased space requirements. Furthermore, it may be beneficial to modify the switching conditions such that switching losses are reduced. Improved driver chips, improved semiconductor packages as well as improved methods for driving a power transistor may help with solving these and other problems.

### SUMMARY

Various aspects pertain to a driver chip configured to drive a gate of a power transistor, the driver chip comprising: a slope reference configured to provide a first voltage, an output configured to be connected to a gate terminal of a power transistor, a shaping capacitor configured to be connected between the slope reference and a drain terminal of the power transistor, and a buffer connected between the slope reference and the output and configured to be provided with the first voltage.

Various aspects pertain to a driver chip configured to drive a gate of a power transistor, the driver chip comprising: a slope reference configured to provide a first voltage, an output configured to be connected to a gate terminal of a power transistor, and a shaping capacitor configured to be connected between the slope reference and a drain terminal of the power transistor device, wherein the shaping capacitor consists of a diode.

Various aspects pertain to a semiconductor package, comprising: a driver chip as outlined above, and a power transistor chip, wherein the driver chip is configured to drive a power transistor of the power transistor chip.

Various aspects pertain to a method for driving a power transistor, the method comprising: providing a driver chip and a power chip, the power chip comprising a power transistor, providing, using a slope reference of the driver chip, a first voltage, connecting an output of the driver chip to a gate terminal of the power transistor, connecting a shaping capacitor of the driver chip between the slope reference and a drain terminal of the power transistor, driving a gate of the power transistor using the supply voltage, wherein the shaping capacitor shapes a transition between an on state and an off state of the power transistor, and using a buffer of the driver chip to buffer the shaping capacitor from a gate-drain capacitance of the power transistor, wherein the first voltage is provided to an input of the buffer.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B schematically illustrate a driver chip configured to drive a power transistor, wherein the driver chip comprises a shaping capacitor configured to shape a transient of the power transistor and a buffer configured to buffer the shaping capacitor from the power transistor. FIG. 1A shows the driver chip alone and

FIG. 1B shows the driver chip connected to a power transistor.

FIG. 2 illustrates an exemplary transient of a power transistor in the case that a driver chip like the driver chip of FIGS. 1A and 1B is used to drive the power transistor, wherein the driver chip comprises a linear shaping capacitor.

FIG. 3 schematically illustrates the capacitance of a diode as a function of applied voltage in reverse bias. Such a diode may be used in the driver chip of FIGS. 1A and 1B as a non-linear shaping capacitor.

FIGS. 4A and 4B schematically illustrate further exemplary driver chips, wherein the shaping capacitor is a non-linear capacitor.

FIG. 5 schematically illustrates a further exemplary driver chip comprising two diodes in an anti-parallel connection as shaping capacitors.

FIG. 6 illustrates an exemplary transient of a power transistor in the case that the driver chip of FIG. 5 is used to drive the power transistor.

FIG. 7 illustrates a shaping capacitor circuit which may be part of a driver chip, wherein the shaping capacitor circuit comprises two switches and wherein the body diodes of the switches may be used as shaping capacitors.

FIG. 8 schematically illustrates a further exemplary driver chip, wherein the shaping capacitor is external to the driver chip.

FIG. 9 schematically illustrates a power electronic device, for example a semiconductor package, comprising a driver chip and a power transistor chip.

FIG. 10 is a flow chart of an exemplary method for driving a power transistor.

The method may for example be performed using the driver chip disclosed in one of the previous Figures.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

A driver chip may be manufactured from specific semiconductor material, for example Si. A power transistor chip may for example be manufactured from a semiconductor material like Si, SiC, SiGe, GaAs, GaN, or from any other suitable semiconductor material.

An efficient driver chip, an efficient semiconductor package as well as an efficient method for driving a power transistor may for example reduce material consumption, ohmic losses, chemical waste, etc. and may thus enable energy and/or resource savings. Improved methods and devices, as specified in this description, may thus at least indirectly contribute to green technology solutions, i.e. climate-friendly solutions providing a mitigation of energy and/or resource use.

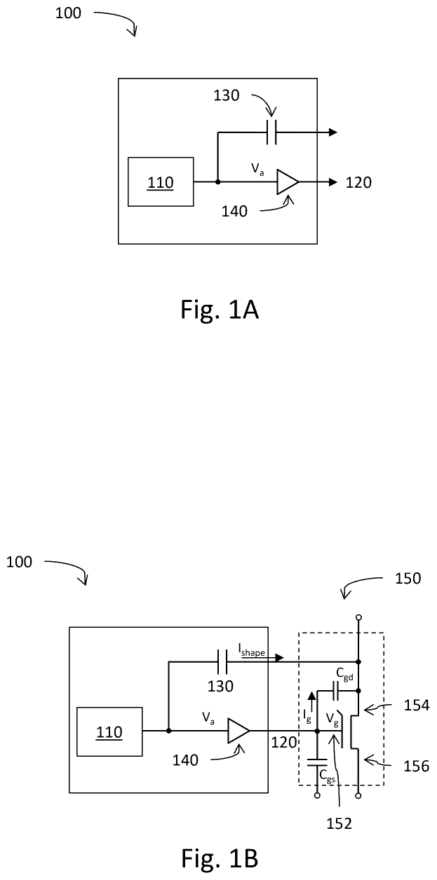

FIG. 1A schematically shows a driver chip 100 configured to drive a gate of a power transistor. The driver chip 100 comprises a slope reference 110, an output 120, a shaping capacitor 130 and a buffer 140. FIG. 1B shows an exemplary application, wherein the driver chip 100 is connected to a power transistor 150.

The driver chip 100 may be configured to drive any suitable power transistor. For example, the driver chip 100 may be configured to drive a GaN power transistor or a high electron mobility transistor (HEMT). The driver chip 100 may for example be configured for use in motor drive applications. However, the driver chip 100 may also be configured for use in any other suitable application. According to an example, the driver chip 100 comprises or consists of a Si chip.

The driver chip 100 may be configured to be connected to a supply voltage. The supply voltage may for example be V_{DD}. The supply voltage may for example be in the range of about 1V to about 60V, for example about 3V. The driver chip 100 may for example comprise a signal generator, wherein the signal generator may use the supply voltage to generate a pulse width modulated signal. The slope reference 110 is configured to provide a first voltage (Vₐ in FIGS. 1A and 1B). The slope reference 110 may for example correspond to the signal generator mentioned above. The first voltage Vₐ is provided to the buffer 140 and via the buffer 140 may be used to drive a gate of the power transistor 150.

The output 120 is configured to be connected to the gate terminal of the power transistor 150. The driver chip 100 may be configured to supply a pulse width modulated signal to the gate of the power transistor 150 via the output 120 in order to turn on the power transistor 150 or to turn off the power transistor 150.

The shaping capacitor 130 is configured to be connected between the slope reference 110 and a drain terminal of the power transistor 150. The shaping capacitor 130 may be an internal component of the driver chip 100. The shaping capacitor 130 may be a part comprising Si and one or more dielectric layers. For example, in the case that the shaping capacitor 130 is a linear capacitor (see further below), the shaping capacitor 130 may comprise a layer stack comprising a dielectric layer sandwiched between two metal layers. In the case that the shaping capacitor 130 is a non-linear capacitor (see further below), the shaping capacitor 130 may comprise a p-doped Si layer and an n-doped Si layer.

The shaping capacitor 130 may be configured to shape a voltage transition of a power transistor being driven by the driver chip 100 when the power transistor is switched from an off-state to an on-state or vice versa. For example, the shaping capacitor 130 may be configured to set a steepness of the voltage transition. The steepness of the voltage transition may for example determine an electro-magnetic interference (EMI) caused by the transition, wherein steeper transitions may cause stronger EMI. On the other hand, flatter transitions may cause larger switching losses. A size of the shaping capacitor 130 may therefore be chosen such that an acceptable compromise between EMI and switching losses is achieved.

According to an example, the shaping capacitor 130 has a capacitance of about 500 fF or less, or about 400 fF or less, or about 300 fF or less, or about 200 fF or less. According to another example, the capacitor has a higher capacitance. However, it may be desirable to use a capacitor with a comparatively low capacitance, for example because a capacitor with a lower capacitance may be easier to implement in the driver chip 100 than a capacitor with a comparatively higher capacitance. According to an example, the capacitance of the shaping capacitor 130 is at least one order of magnitude smaller than a gate-drain capacitance of the power transistor.

The buffer 140 is connected between the slope reference 110 and the output 120 of the driver chip 100. The buffer 140 may be configured buffer the shaping capacitor 130 from the power transistor being driven by the driver chip 100. Without the buffer 140, the capacitance of the shaping capacitor 130 would have to be at least as large as the gate-drain capacitance of the power transistor in order for the shaping capacitor 130 to have a noticeable effect on the voltage transition of the power transistor. The gate-drain capacitance of a typical power transistor however may for example be in the range of several hundred pF and integrating into the driver chip 100 a capacitor with such a large capacitance may be comparatively expensive.

The buffer 140 may be any suitable type of buffer. The buffer 140 may in particular be a voltage buffer. However, it may be necessary that the buffer 140 supports fast operation and the buffer 140 may for example have to have a bandwidth of about 100 MHz. For example, the buffer 140 may be a buffer amplifier or unity gain buffer or back-to-back follower (e.g. an NMOS-PMOS follower).

FIG. 1B shows the driver chip 100 connected to a power transistor 150, wherein the power transistor may for example be a HEMT. The power transistor 150 is drawn using dashed lines in order to emphasize that the power transistor 150 is external to the driver chip 100.

As shown in FIG. 1B, the output 120 of the driver chip 100 is connected to a gate terminal 152 of the power transistor 150. Furthermore, the shaping capacitor 130 may be connected to a drain terminal 154 of the power transistor 150. FIG. 1B also shows the source terminal 156 and the (parasitic) gate-drain capacitance C_{gd} and gate-source capacitance Cgs of the power transistor 150.

The driver chip 100 may be configured to direct a shaping current Iₛₕₐₚₑ through the shaping capacitor 130. The shaping current Iₛₕₐₚₑ may be provided by an internal current source of the driver chip 100. For example, the shaping current Iₛₕₐₚₑ may be provided by the slope reference 110. A steepness of a voltage transition dV/dt of the power transistor 150 may in that case be defined by:

$$\frac{dV}{dt} = \frac{{I}_{shape}}{{C}_{shape}} ,$$

wherein Cₛₕₐₚₑ is the capacitance of the shaping capacitor 130.

The driver chip 100 may also cause a gate current I_{g} which charges the gate-drain capacitance C_{gd} of the power transistor. Furthermore, the gate of the power transistor 150 may have a gate voltage V_{g} and an input of the amplifier 140 may have a voltage Vₐ, wherein Vₐ may be the target voltage of V_{g}. Vₐ may for example be about 3V.

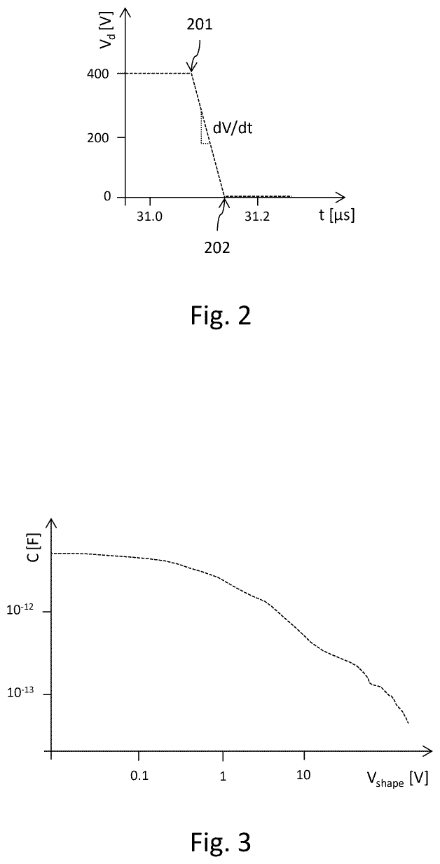

FIG. 2 schematically shows the voltage transition in the Miller plateau of a power transistor driven by the driver chip 100, according to an example. The numerical values for time on the x-axis and the drain voltage (measured against ground potential) on the y-axis are for a typical power transistor which the driver chip 100 may be configured to drive.

FIG. 2 in particular shows the effect of the shaping capacitor 130 on the voltage transition: the transition from a high drain voltage to zero drain voltage has a defined slope dV/dt which is set by the shaping capacitor 130. Without the shaping capacitor 130, the slope of the transition may e.g. be significantly steeper which would cause strong radiated EMI. Shaping a voltage transition with the shaping capacitor 130 as shown in FIG. 2 may for example reduce EMI emissions. The expected shape of a radiated EMI spectrum of the transition shown in FIG. 2 may be calculated as sinc (nπfₛτ), wherein n is the Fast Fourier transform index, fₛ is the switching frequency and τ is the duration of the transition.

Note however that FIG. 2 shows the voltage transition of the power transistor in the case that the shaping capacitor 130 is a linear capacitor. In this context, “linear capacitor” may mean that the capacitance of the capacitor is constant, i.e. independent of the applied voltage. For example, a metal capacitor comprising two or more metal plates separated by dielectric layer(s) is such a linear capacitor. According to an example, a linear capacitor may be internal to the driver chip 100, as shown in FIGS. 1A and 1B. According to another example, a linear capacitor may be external to the driver chip 100 and may for example be a surface mounted device.

Using a linear capacitor however may cause sharp edges 201, 202 in the voltage transition, compare FIG. 2. These sharp edges 201, 202 may essentially comprise discontinuities in the first derivative of the voltage transition. These sharp edges 201, 202 may significantly contribute to EMI generated by switching the power transistor. In particular, the sharp edges 201, 202 may contribute to high frequency EMI. In order to further mitigate EMI, it may therefore be beneficial to not only set the slope of the transition to a predefined value as shown in FIG. 2, but to also eliminate the sharp edges 201, 202. Modifying the voltage transition such that it exhibits a Gaussian S-shape may therefore be beneficial for EMI mitigation purposes.

However, it may not be technically possible or it may be comparatively complex and/or expensive to provide a voltage transition with a Gaussian S-shape using active feedback-controlled switching. Active feedback-controlled switching may be viable for transition times t in the range of hundreds of nanoseconds. A GaN based power transistor however may have transition times of e.g. about 50 ns or even less.

Instead of using active feedback-controlled switching, the voltage transition may be modified to exhibit a Gaussian S-shape by providing a shaping capacitor 130 that is a suitable non-linear capacitor. In this context, a “non-linear capacitor” has a capacitance which (strongly) depends on the applied voltage. An example for a suitable non-linear capacitor is a diode, for example a diode configured to handle a comparatively high voltage. The junction capacitance of a diode inversely depends on the depletion width and is therefore inversely proportional to the junction voltage in reverse direction.

FIG. 3 schematically shows the capacitance of a suitable diode as a function of applied voltage in reverse bias. Note the double logarithmic scale on the axes. As shown in FIG. 3, the capacitance of the exemplary non-linear capacitor increases with decreasing applied voltage. This slows down the voltage transition of a power transistor when the voltage becomes small. In other words, using a non-linear capacitor with a voltage dependence as shown in FIG. 3 as the shaping capacitor 130, one of the sharp edges 201 and 202 can be smoothed out.

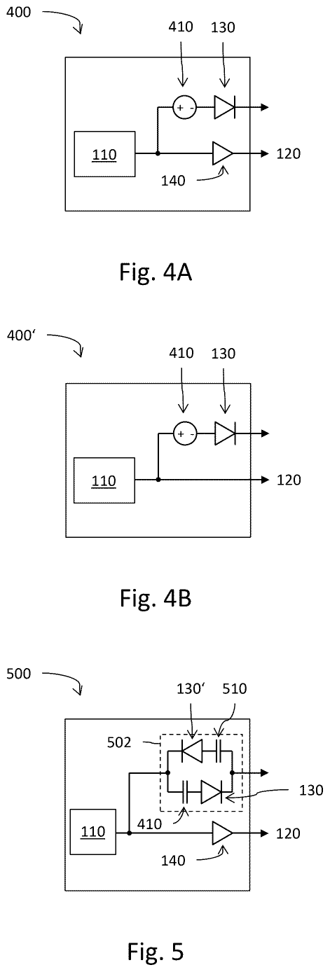

FIG. 4A shows a driver chip 400 which may be similar or identical to the driver chip 100, except for the differences described in the following. In particular, the driver chip 400 comprises a non-linear shaping capacitor 130 with a capacitance that is voltage dependent as e.g. shown in FIG. 3. According to an example, the shaping capacitor 130 is implemented using a diode.

As shown in FIG. 4A, the driver chip 400 may further comprise a voltage source 410 connected in series with the non-linear shaping capacitor (in this case, a diode) 130. The voltage source 410 may be configured to prevent the diode 130 from becoming forward biased when the drain voltage falls below the gate voltage. The voltage source 410 may for example be configured to provide a voltage of about 3V. According to an example, the voltage source 410 may be a linear capacitor.

However, the driver chip 400 may only be configured to smooth out the voltage transition at one end, for example only at the edge 201 but not at the edge 202, compare FIG. 2. In order to smooth out the voltage transition at both ends, it may be necessary to use two non-linear capacitors as for example shown in FIG. 5.

FIG. 4B shows a driver chip 400′ which may be similar or identical to the driver chip 400, except that the driver chip 400′ does not comprise the buffer 140. For this reason, the shaping capacitor 130, which may e.g. be a diode, of the driver chip 400′ may need to have a larger capacitance than the shaping capacitor 130 of the driver chip 400.

FIG. 5 shows a further driver chip 500 which may be similar or identical to the driver chip 400 or 400′, except that the driver chip 500 additionally comprises a second non-linear shaping capacitor 130′. The second shaping capacitor 130′ may be the same type of non-linear capacitor as the shaping capacitor 130, for example the same type of diode. The shaping capacitor 130 and the second shaping capacitor 130′ are provided in an antiparallel connection. In this manner, the shaping capacitor 130 can be used to smooth out one of the edges 201, 202 and the second shaping capacitor 130′ can be used to smooth out the other one of the edges 201, 202.

As also shown in FIG. 5, the driver chip 500 may further comprise a second voltage source 510 connected in parallel with the second shaping capacitor 130′. In a similar manner to the voltage source 410 and the shaping capacitor 130, the second voltage source 510 is configured to prevent the second shaping capacitor 130′ from becoming forward biased. According to an example, the second voltage source 510 is a linear capacitor (and, as mentioned previously, the voltage source 410 may also be a linear capacitor). The shaping capacitors 130, 130′ and the voltage sources (linear capacitors) 410, 510 may form a shaping capacitor circuit 502 of the driver chip 500.

The shaping capacitor 130 and the second shaping capacitor 130′ may for example have identical capacitances. It is however also possible that the shaping capacitors 130, 130′ have different capacitances. According to an example, the voltage sources 410, 510 are linear capacitors that have larger capacitances than the shaping capacitors 130, 130′. The capacitance of the linear capacitors may for example be at least one order of magnitude larger than the capacitance of the shaping capacitors 130, 130′.

The order in which the shaping capacitor 130 and the voltage source 410 are arranged in a serial connection may not be important and the positions of the shaping capacitor 130 and the voltage source 410 may be swapped compared to what is shown in FIG. 5. Similarly, the positions of the second shaping capacitor 130′ and the second voltage source 510 may be swapped.

According to an example, the buffer 140 is omitted from the driver chip 500, similar to the case of the driver chip 400′ shown in FIG. 4B.

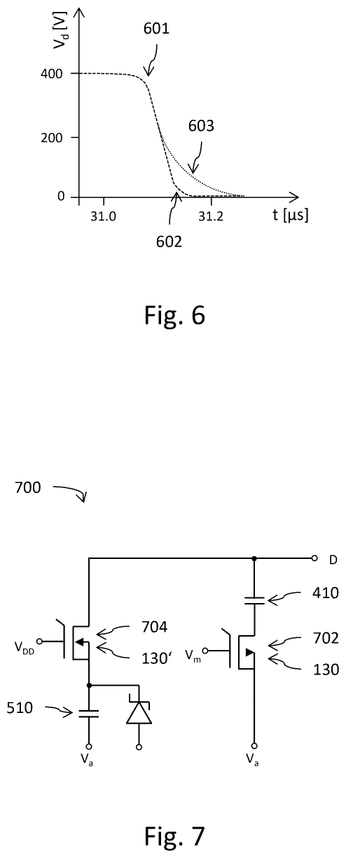

FIG. 6 schematically shows the voltage transition in the Miller plateau of a power transistor driven by the driver chip 500. As shown in FIG. 6, the sharp edges 201, 202 shown in FIG. 2 are smoothed out by the non-linear shaping capacitors 130, 130′. Instead, the voltage transition essentially has an S-shape with smoothed curves 601, 602 at the beginning and the end of the transient.

The shaping capacitors 130, 130′ may have a further effect on the voltage transition in the case that the power transistor driven by the driver chips 100-500 is a GaN device: GaN transistors have parasitic gate-drain capacitances that are non-linear, wherein the capacitance significantly increases when the drain voltage decreases sufficiently. For this reason, the voltage transition in the Miller plateau significantly slows down if no shaping capacitor is used. This case is indicated by the dotted line 603 in FIG. 6. This comparatively flat transition however increases switching losses of the power transistor. The shaping capacitors 130, 130′ therefore not only help with reducing EMI but may also help with reducing the switching losses of the power transistor.

In the case that the voltage sources 410, 510 are capacitors, these capacitors are floating capacitors in the exemplary implementation shown in FIG. 5. It may be beneficial to actively control the charge of these capacitors, using for example a sample and hold circuit. This may for example be advantageous in the case that the maximum drain voltage changes between switching cycles of the power transistor. For example: during one cycle the maximum drain voltage may be 400V and in the subsequent cycle the maximum drain voltage may be only 300V. If floating capacitors as shown in FIG. 5 were used, this would cause the S-shaped voltage transition to lose the smoothed transition at 601. This can be averted by essentially making the respective diode conductive while the drain voltage is high, such that the respective linear capacitor receives the actual maximum drain voltage that is currently applied instead of a (potentially higher) maximum drain voltage that was applied in a previous cycle.

FIG. 7 shows an exemplary implementation of a shaping capacitor circuit 700 that may be used in place of the shaping capacitor circuit 502 shown in FIG. 5. The shaping capacitor circuit 700 essentially comprises a first integrated switch 702 and a second integrated switch 704 instead of diodes as shaping capacitors 130, 130′. The first integrated switch 702 may be a p-channel MOSFET (PMOS) and the second integrated switch 704 may be an n-channel MOSFET (NMOS). In FIG. 7, D denotes the drain contact of the circuit and Vₘ and V_{DD} are bias voltages.

When the first integrated switch 702 becomes conductive, the capacitor at 410 may receive the drain voltage, for example 300V, and when the second integrated switch 704 becomes conductive, the capacitor at 510 may receive the gate voltage, for example 3V. When the channels of the first integrated switch 702 and the second integrated switch 704 are closed, the body diodes of the first and second integrated switches 702, 704 act as non-linear shaping capacitors 130, 130′, taking the place of the simple diodes mentioned with respect to FIG. 5. In other words, in the example shown in FIG. 7 a junction-capacitance of a semiconductor junction provides the non-linearity of the shaping capacitor.

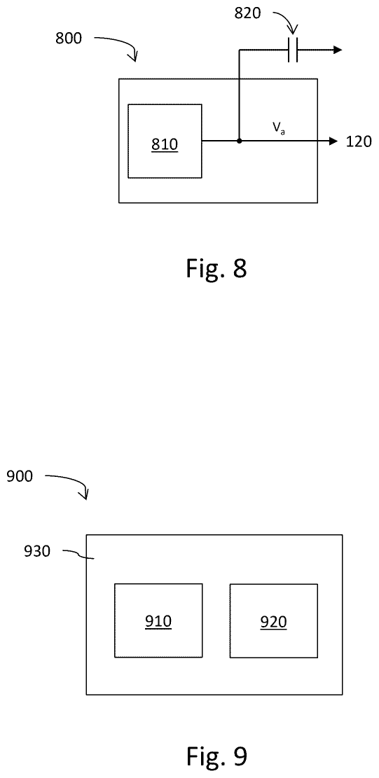

FIG. 8 shows a driver chip 800 which may be similar or identical to the driver chip 100, except for the differences described in the following. In particular, the driver chip 800 does not comprise the buffer 140 of the driver chip 100.

The driver chip 800 may comprise a switchable voltage source or signal generator 810 configured to generate a modulated signal for driving a gate of a power transistor. The switchable voltage source or signal generator 810 may correspond to the slope reference 110 of the previous examples. The signal is provided to the gate of the power transistor via the output 120. As shown in FIG. 8, no buffer is arranged between the voltage source 810 and the output 120.

Since the driver chip 800 does not comprise the buffer 140, a shaping capacitor may need to have a larger capacitance than in the case that the buffer 140 is present. For this reason, the driver chip 800 does not comprise an internal shaping capacitor. Instead, an external shaping capacitor 820 is provided. The external shaping capacitor 820 may for example be a linear capacitor. The external shaping capacitor 820 may for example be a metal capacitor. The driver chip 800 and the external shaping capacitor 820 may for example be parts of a common semiconductor package. The external shaping capacitor 820 may for example be a surface mounted device. According to an example, the external shaping capacitor has a capacitance of about 100 pF or more, for example 200 pF or more, or 300 pF or more, or 500 pF or more.

According to another example, the driver chip 800 does comprise the buffer 140, wherein the buffer 140 is arranged between the voltage source 810 and the output 120. In this case however, the shaping capacitor 820 is still external to the driver chip 800, according to an example. According to another example, the shaping capacitor 820 is internal to the driver chip 800, similar to the case shown in FIG. 1A.

FIG. 9 shows a power electronic device 900 comprising a driver chip 910 and a power transistor chip 920, wherein the driver chip 910 is configured to drive a gate of a power transistor of the power transistor 920. The driver chip 910 may for example correspond to one of the driver chips 100 to 800 and the power transistor of the power transistor chip 920 may for example correspond to the power transistor 150, compare FIG. 1B. The power electronic device 900 further comprises an encapsulation 930 encapsulating the driver chip 910 and configured to protect the driver chip 910 from environmental influences.

According to an example, the power transistor chip 920 is also encapsulated by the encapsulation 930. According to another example, power transistor chip 920 is encapsulated by a different, second encapsulation. The power electronic device 900 may for example comprise or consist of a semiconductor package or a semiconductor module. In the latter case, the driver chip 910 may be arranged on a driver board and the power transistor chip 920 may be arranged on a power electronic substrate like a DCB. The driver board may for example be arranged over the power electronic substrate.

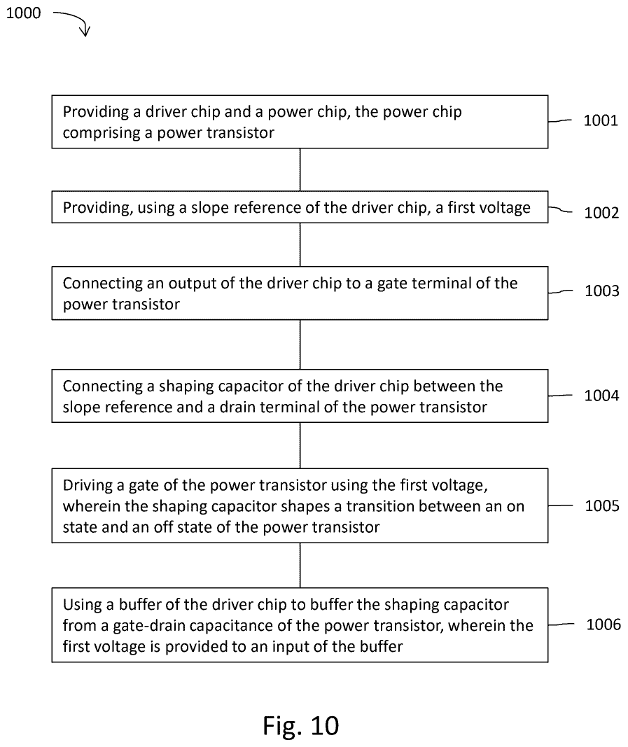

FIG. 10 is a flow chart of an exemplary method 1000 for driving a power transistor. The method 1000 may for example be performed using the driver chips 100 to 800.

The method 1000 comprises at 1001 a process of providing a driver chip and a power chip, the power chip comprising a power transistor. At 1002 the method 1000 comprises a process of providing, using a slope reference of the driver chip, a first voltage, at 1003 a process of connecting an output of the driver chip to a gate terminal of the power transistor, at 1004 a process of connecting a shaping capacitor of the driver chip between the slope reference and a drain terminal of the power transistor, at 1005 a process of driving a gate of the power transistor using the first voltage, wherein the shaping capacitor shapes a transition between an on state and an off state of the power transistor, and at 1006 a process of using a buffer of the driver chip to buffer the shaping capacitor from a gate-drain capacitance of the power transistor, wherein the first voltage is provided to an input of the buffer.

### EXAMPLES

Example 1 is a driver chip configured to drive a gate of a power transistor, the driver chip comprising: a slope reference configured to provide a first voltage, an output configured to be connected to a gate terminal of a power transistor, a shaping capacitor configured to be connected between the slope reference and a drain terminal of the power transistor, and a buffer connected between the slope reference and the output and configured to be provided with the first voltage.

Example 2 is the driver chip of example 1, wherein a capacitance of the shaping capacitor is at least one order of magnitude smaller than a gate-drain capacitance of the power transistor.

Example 3 is the driver chip of one of the preceding examples, wherein the shaping capacitor is a linear capacitor.

Example 4 is the driver chip of one of examples 1 or 2, wherein the shaping capacitor is a non-linear capacitor.

Example 5 is the driver chip of example 4, wherein a junction-capacitance of a semiconductor junction provides the non-linearity of the shaping capacitor.

Example 6 is the driver chip of example 5, wherein the shaping capacitor consists of a first and a second diode in an antiparallel connection.

Example 7 is the driver chip of example 6, further comprising: a first capacitor connected in series with the first diode and a second capacitor connected in series with the second diode.

Example 8 is the driver chip of example 6 or 7, wherein the first and second diodes are body diodes of first and second integrated switches, wherein the first integrated switch is configured to charge the first capacitor up to a maximum drain-to-source voltage of the power transistor and wherein the second integrated switch is configured to charge the second capacitor up to a maximum gate-to-source voltage the power transistor.

Example 9 is the driver chip of one of the preceding examples, wherein the driver chip is configured to drive a high electron mobility transistor.

Example 10 is a driver chip configured to drive a gate of a power transistor, the driver chip comprising: a slope reference configured to provide a first voltage, an output configured to be connected to a gate terminal of a power transistor, and a shaping capacitor configured to be connected between the slope reference and a drain terminal of the power transistor device, wherein the shaping capacitor consists of a diode.

Example 11 is the driver chip of example 10, wherein the shaping capacitor consists of a first and a second diode in an antiparallel connection.

Example 12 is the driver chip of example 11, further comprising: a first capacitor connected in series with the first diode and a second capacitor connected in series with the second diode.

Example 13 is a semiconductor package, comprising: the driver chip of one of the preceding examples, and a power transistor chip, wherein the driver chip is configured to drive a power transistor of the power transistor chip.

Example 14 is the semiconductor package of example 13, wherein the power transistor chip is a GaN chip.

Example 15 is the semiconductor package of example 13 or 14, wherein the semiconductor package is configured for use in motor drive applications.

Example 16 is a method for driving a power transistor, the method comprising: providing a driver chip and a power chip, the power chip comprising a power transistor, providing, using a slope reference of the driver chip, a first voltage, connecting an output of the driver chip to a gate terminal of the power transistor, connecting a shaping capacitor of the driver chip between the slope reference and a drain terminal of the power transistor, driving a gate of the power transistor using the first voltage, wherein the shaping capacitor shapes a transition between an on state and an off state of the power transistor, and using a buffer of the driver chip to buffer the shaping capacitor from a gate-drain capacitance of the power transistor, wherein the first voltage is provided to an input of the buffer.

Example 17 is the method of example 16, wherein a capacitance of the shaping capacitor is at least one order of magnitude smaller than the gate-drain capacitance.

Example 18 is the method of example 16 or 17, wherein the shaping capacitor is a linear capacitor.

Example 19 is the method of example 16 or 17, wherein the shaping capacitor is a non-linear capacitor.

Example 20 is an apparatus for performing the method according to anyone of examples 16 to 19.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

1. A driver chip configured to drive a gate of a power transistor, the driver chip comprising:
a slope reference generator configured to provide a first voltage,
an output node configured to drive a gate terminal of a power transistor,
a shaping capacitor connected between the slope reference generator and a drain terminal of the power transistor, and
a buffer connected between the slope reference generator and the output node, the buffer configured to receive the first voltage.

2. The driver chip of claim 1, wherein a capacitance of the shaping capacitor is at least one order of magnitude smaller than a gate-drain capacitance of the power transistor.

3. The driver chip of claim 1, wherein the shaping capacitor is a linear capacitor.

4. The driver chip of claim 1, wherein the shaping capacitor is a non-linear capacitor.

5. The driver chip of claim 4, wherein a junction-capacitance of a semiconductor junction provides the non-linearity of the shaping capacitor.

6. The driver chip of claim 5, wherein the shaping capacitor includes a first diode and a second diode disposed in an antiparallel connection.

7. The driver chip of claim 6, further comprising:
a first capacitor connected in series with the first diode and a second capacitor connected in series with the second diode.

8. The driver chip of claim 1, wherein the driver chip is configured to drive a high electron mobility transistor.

9. A driver chip configured to drive a gate of a power transistor, the driver chip comprising:
a slope reference generator configured to provide a first voltage,
an output node operative to drive a gate terminal of a power transistor, and
a shaping capacitor connected between the slope reference generator and a drain terminal of the power transistor device,
wherein the shaping capacitor includes a diode.

10. The driver chip of claim 9, wherein the shaping capacitor includes a first diode and a second diode disposed in an antiparallel connection.

11. The driver chip of claim 10, further comprising:
a first capacitor connected in series with the first diode and a second capacitor connected in series with the second diode.

12. A semiconductor package, comprising:
the driver chip of claim 1, and
a power transistor chip,
wherein the driver chip is configured to drive a power transistor of the power transistor chip.

13. The semiconductor package of claim 12, wherein the power transistor chip is a GaN chip.

14. The semiconductor package of claim 13, wherein the semiconductor package is configured for use in motor drive applications.

15. A method for driving a power transistor, the method comprising:
providing a driver chip and a power chip, the power chip comprising a power transistor,
providing, using a slope reference generator of the driver chip, a first voltage,
connecting an output node of the driver chip to a gate terminal of the power transistor,
connecting a shaping capacitor of the driver chip between the slope reference generator and a drain terminal of the power transistor,
driving a gate of the power transistor using the first voltage, wherein the shaping capacitor shapes a transition between an on state and an off state of the power transistor, and
using a buffer of the driver chip to buffer the shaping capacitor from a gate-drain capacitance of the power transistor, wherein the first voltage is provided from the applet node of the driver chip to an input of the buffer.

16. The method of claim 15, wherein a capacitance of the shaping capacitor is at least one order of magnitude smaller than the gate-drain capacitance.

17. The method of claim 15, wherein the shaping capacitor is a linear capacitor.

18. The method of claim 15, wherein the shaping capacitor is a non-linear capacitor.

19. The driver chip of claim 6, wherein the first diode and second diode are body diodes of a first integrated switch and a second integrated switch, wherein the first integrated switch is configured to charge the first capacitor up to a maximum drain-to-source voltage of the power transistor and wherein the second integrated switch is configured to charge the second capacitor up to a maximum gate-to-source voltage the power transistor.
